(19) United States
(12) Patent Application Publication
(10) Pub. No.: US 2010/0025757 A1
(43) Pub. Date: Feb. 4, 2010

(54) Conductive structure and vertical-type pillar transistor

(75) Inventors: Yong-Hoon Son, Yongin-si (KR); Jong-Wook Lee, Yongin-si (KR); Jong-Hyuk Kang, Suwon-si (KR)

Correspondence Address: MILLS & ONELLO LLP, ELEVEN BEACON STREET, SUITE 605, BOSTON, MA, 02108, US

(73) Assignee: Samsung Electronics Co., Ltd., Suwon-si (KR)

(21) Appl. No.: 12/459,071

(22) Filed: Jun. 26, 2009

(30) Foreign Application Priority Data
Jun. 27, 2008 (KR) 10-2008-0061785

(51) Int. Cl. H01L 29/78

(52) U.S. Cl. 257/329; 257/E29.262

(57) ABSTRACT

In a conductive structure, method of forming the conductive structure, a vertical-type pillar transistor and a method of manufacturing the vertical-type pillar transistor, the conductive structure includes a pillar provided on a substrate. A first conductive layer pattern is provided on a sidewall of the pillar, at least a portion of the first conductive layer pattern facing the sidewall of the pillar. A second conductive layer pattern is provided on a surface of the first conductive layer pattern, the second conductive layer pattern facing the sidewall of the pillar. A hard mask pattern covers upper surfaces of the first conductive layer pattern and the pillar. The conductive structure includes an electric conductor with a relatively low resistance. The conductive structure may be used as an electrode of a memory device.

### RELATED APPLICATION

This application claims priority under 35 U.S.C. 119 to Korean Patent Application number 10-2008-0061785, filed in the Korean Intellectual Property Office on Jun. 27, 2008, the entire contents of which are incorporated herein in their entirety by reference.

### BACKGROUND

1. Field

Exemplary embodiments relate to a conductive structure, method of forming the conductive structure, a vertical-type pillar transistor and a method of manufacturing the vertical-type pillar transistor. More particularly, exemplary embodiments relate to a conductive structure in which a semiconductor pillar and a conductive pattern facing the semiconductor pillar are stacked, a method of forming the conductive structure, a vertical-type pillar transistor including the conductive structure and a method of manufacturing the same.

2. Description of the Related Art

Generally, as semiconductor devices become highly integrated, dimensions of active regions are reduced, and channel lengths of MOS transistors formed in the active regions are reduced. As the channel length of the MOS transistor is reduced, electric fields or potentials in the channel regions are dramatically affected by a source or drain, and short channel effects arise. When the short channel effects occur, a leakage current is increased, a threshold voltage is decreased and a current affected by a drain voltage is increased. Accordingly, it becomes difficult to control the MOS transistor using a gate.

Thus, methods of scaling down devices formed on a substrate and improving characteristics of the devices have been researched. For example, a vertical-type pillar transistor including a channel region formed in a vertical direction relative to a substrate has been researched. In the vertical-type pillar transistor, a semiconductor pattern having a pillar shape on the substrate is used as the channel region. Even though a horizontal area in the substrate is not widened, the height of the semiconductor pattern having a pillar shape may be controllable to be increased to provide a desired channel length.

Since the vertical-type pillar transistor is formed in the semiconductor pattern, not in the bulk substrate, characteristics of the semiconductor pattern may be very important for performance characteristics of the transistor. For example, when the semiconductor pattern has any crystal defect, leakage current properties and threshold voltages in the vertical-type pillar transistor formed in each of the semiconductor patterns may not be uniform. However, because it is considerably more difficult to form the semiconductor pattern for the vertical-type pillar transistor without any crystal defects than it is to form the bulk substrate without any crystal defects, it may be not easy to ensure electrical properties of the vertical-type pillar transistors.

In particular, it may be difficult to form a source/drain in both sides of the semiconductor pillar by an ion implantation process at one time. Additionally, the ion implantation process may not be easily controlled to form the source/drain in a desired region accurately.

Further, it may be difficult to form a gate electrode in the middle portion of the semiconductor pillar, along with ensuring that the source/drain is formed in both of the sides of the semiconductor pillar. Moreover, it may not be easy to form the gate electrode having a low resistance.

For example, in a manufacture of a conventional planar-type transistor, a metal or metal silicide having a low resistance is formed vertically on a polysilicon material to form a gate electrode. That is, the resistance of the gate electrode is reduced by the low resistive metal material. However, in a vertical-type pillar transistor, even though the polysilicon material and the metal silicide material are formed vertically on a substrate, since the conductive materials are stacked in the same direction as a direction where the channel is formed, the resistance of the gate electrode is not reduced. That is, when the polysilicon material and the metal silicide material are stacked vertically on the substrate, a portion of the gate facing the channel region includes polysilicon and another portion of the gate facing the channel region includes metal silicide.

Therefore, because the resistance of the gate electrode is not reduced by using the method of manufacturing the planar-type transistor, it may be difficult to reduce the resistance of the vertical-type pillar transistor.

Accordingly, a new method for manufacture of a vertical-type pillar transistor having a structure capable of reducing the resistance of the gate electrode thereof is required.

### SUMMARY

Exemplary embodiments provide a conductive structure including a conductive pattern facing a semiconductor pillar to provide a low resistance.

Exemplary embodiments provide a method of forming the conductive structure.

Exemplary embodiments provide a vertical-type pillar transistor including a gate with a low resistance.

Exemplary embodiments provide a method of manufacturing the vertical-type pillar transistor.

According to some exemplary embodiments, a conductive structure includes a pillar provided on a substrate. A first conductive layer pattern is provided on a sidewall of the pillar, at least a portion of the first conductive layer pattern facing the sidewall of the pillar. A second conductive layer pattern is provided on a surface of the first conductive layer pattern, the second conductive layer pattern facing the sidewall of the pillar. A hard mask pattern covers upper surfaces of the first conductive layer pattern and the pillar.

In an exemplary embodiment, the conductive structure may further include an insulation layer pattern making contact with the sidewall of the pillar.

In an exemplary embodiment, the first conductive layer pattern may include a first portion facing the sidewall of the pillar and second portions that are folded from both sides of the first portion to face the substrate respectively.

The second conductive layer pattern may have a shape filling a gap between the second portions included in the first conductive layer pattern.

According to some exemplary embodiments, in a method of manufacturing a conductive structure, a pillar is formed on a substrate. A hard mask pattern is formed to cover an upper surface of the pillar, the hard mask pattern having an area greater than that of the upper surface of the pillar. A first conductive layer pattern is formed on a sidewall of the pillar, at least a portion of the first conductive layer pattern facing the sidewall of the pillar. A second conductive layer pattern is formed on a surface of the first conductive layer pattern, the second conductive layer pattern facing the sidewall of the pillar.

In an exemplary embodiment, the method may further include forming a sacrificial layer on the substrate and partially etching the sacrificial layer to form a mold pattern including an opening that selectively exposes a region for the pillar to be formed.

The pillar may be formed by growing semiconductor material in the opening.

In an exemplary embodiment, to form the hard mask pattern, a hard mask layer may be formed on the pillar and the mold pattern. The hard mask layer may be patterned to form the hard mask pattern covering the pillar, the hard mask pattern having an upper surface wider than the upper surface of the pillar. The sacrificial layer under the hard mask pattern may be removed.

According to some exemplary embodiments, a vertical-type pillar transistor includes a single-crystalline semiconductor pillar provided on a substrate. A gate insulation layer is provided on a sidewall of the single-crystalline semiconductor pillar and a portion of the substrate. A first conductive layer pattern is provided on a surface of the gate insulation layer pattern, at least a portion of the first conductive layer pattern facing the sidewall of the pillar. A second conductive layer pattern is provided on a surface of the first conductive layer pattern, the second conductive layer pattern facing the sidewall of the pillar. A hard mask pattern covers upper surfaces of the first conductive layer pattern and the single-crystalline semiconductor pillar. An impurity region is provided under a surface of the substrate adjacent to the single-crystalline semiconductor pillar.

In an exemplary embodiment, the gate insulation layer may have a folded shape at a contact portion between the substrate and the pillar to insulate the first conductive layer pattern from the substrate.

In an exemplary embodiment, the gate insulation layer may include thermal oxide formed by a thermal oxidation process.

In an exemplary embodiment, the first conductive layer pattern may include a first portion facing the sidewall of the pillar and second portions that are folded from both sides of the first portion to face the substrate respectively. The second conductive layer pattern may have a shape filling a gap between the second portions included in the first conductive layer pattern.

In an exemplary embodiment, a plurality of the single-crystalline semiconductor pillars may be arranged at regular intervals, and the second conductive layer pattern may extend to face the sidewalls of the single-crystalline semiconductor pillars arranged in a direction.

In an exemplary embodiment, the second conductive layer pattern may include a material having a resistance lower than the first conductive layer pattern. The first conductive layer pattern may include polysilicon, and the second conductive layer pattern may include metal or metal silicide.

In an exemplary embodiment, the vertical-type pillar transistor may further include a spacer provided on both sidewalls of the first conductive layer pattern, the second conductive layer pattern and the hard mask pattern.

In an exemplary embodiment, the vertical-type pillar transistor may further include an insulation interlayer covering the substrate and the hard mask pattern and a contact plug penetrating the insulation interlayer to be connected to the substrate.

According to some exemplary embodiments, in a method of manufacturing a vertical-type pillar transistor, an impurity region is formed under a surface of the substrate. A single-crystalline semiconductor pillar is formed on the surface of the substrate corresponding to the impurity region. A hard mask pattern is formed to cover an upper surface of the single-crystalline semiconductor pillar, the hard mask pattern having an area greater than that of the upper surface of the single-crystalline semiconductor pillar. A gate insulation layer is formed on a sidewall of the single-crystalline semiconductor pillar and a portion of the substrate. A first conductive layer is formed conformally on surfaces of the hard mask pattern and the gate insulation layer pattern. A second conductive layer is formed on a surface of the first conductive layer to fill a gap between the single-crystalline semiconductor pillars. The first and second conductive layers are etched using the hard mask pattern to form first and second conductive layer patterns facing the sidewall of the pillar.

In an exemplary embodiment, the method may further include forming a sacrificial layer on the substrate and partially etching the sacrificial layer to form a mold pattern including an opening that selectively exposes a region for the pillar to be formed.

In an exemplary embodiment, to form the single-crystalline semiconductor pillar, a preliminary silicon layer including amorphous silicon may be formed in the opening. The preliminary silicon layer may be thermally treated to undergo phase transition, to form the single-crystalline semiconductor pillar.

In an exemplary embodiment, to form the hard mask pattern, a hard mask layer may be formed on the pillar and the mold pattern. The hard mask layer may be patterned to form the hard mask pattern covering the pillar, the hard mask pattern having an upper surface wider than the upper surface of the pillar. The sacrificial layer under the hard mask pattern may be removed.

In an exemplary embodiment, the method may further include forming a spacer on both sidewalls of the first conductive layer pattern, the second conductive layer pattern and the hard mask pattern.

After forming the spacer, the method may further include forming a first insulation interlayer covering the hard mask pattern to fill a gap between the hard mask patterns, anisotropically etching the first insulation interlayer to form an opening that exposes the surface of the substrate between the spacers; and filling the opening with conductive material to form a pad contact making contact with the surface of the substrate.

According to some exemplary embodiments, a semiconductor structure and a vertical-type pillar transistor include first and second conductive layer patterns facing a semiconductor pillar. Accordingly, a conductive structure and a gate electrode having a low resistance may be formed using a material with a relatively low resistance. Thus, the gate electrode of a vertical-type pillar transistor has a relatively low resistance, to thereby provide a rapid operating speed and excellent operation characteristics.

### BRIEF DESCRIPTION OF THE DRAWINGS

The foregoing and other features and advantages of the invention will be apparent from the more particular description of preferred aspects of the invention, as illustrated in the accompanying drawings in which like reference characters refer to the same parts throughout the different views. The drawings are not necessarily to scale, emphasis instead being placed upon illustrating the principles of the invention.

FIG. 1 is a cross-sectional view illustrating a conductive structure in accordance with a first exemplary embodiment.

FIGS. 2 to 5 are cross-sectional views illustrating a method of manufacturing a conductive structure in accordance with a first exemplary embodiment.

FIGS. 6A and 6B are cross-sectional views illustrating a vertical-type pillar transistor in accordance with a second exemplary embodiment.

FIGS. 7A to 19B are cross-sectional views illustrating a method of manufacturing a vertical-type pillar transistor in accordance with a second exemplary embodiment.

FIGS. 20A and 20B are cross-section views illustrating a DRAM device including a vertical-type pillar transistor in accordance with a second exemplary embodiment.

FIGS. 21A, 21B and 22 are cross-sectional views illustrating a method of manufacturing a DRAM device including a vertical-type pillar transistor in accordance with a second exemplary embodiment.

FIGS. 23A and 23B are cross-sectional views illustrating a vertical-type transistor in accordance with a third exemplary embodiment.

FIGS. 24 and 25 are cross-sectional views illustrating a method of manufacturing a vertical-type pillar transistor in accordance with a third exemplary embodiment.

FIG. 26 is a cross-sectional view illustrating a memory device including a vertical-type pillar transistor in accordance with a fourth exemplary embodiment.

FIG. 27 illustrates another embodiment.

FIG. 28 illustrates yet another embodiment.

FIG. 29 illustrates a further embodiment.

FIG. 30 illustrates a still further embodiment of the present invention.

### DETAILED DESCRIPTION OF THE EMBODIMENTS

This application claims priority under 35 U.S.C. §119 to Korean Patent Application No. 2008-61785, filed on Jun. 27, 2008 in the Korean Intellectual Property Office (KIPO), the contents of which are herein incorporated by reference in their entirety.

Various exemplary embodiments will be described more fully hereinafter with reference to the accompanying drawings, in which some exemplary embodiments are shown. The present invention may, however, be embodied in many different forms and should not be construed as limited to the exemplary embodiments set forth herein. Rather, these exemplary embodiments are provided so that this description will be thorough and complete, and will fully convey the scope of the present invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular exemplary embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Exemplary embodiments are described herein with reference to cross-sectional illustrations that are schematic illustrations of idealized exemplary embodiments (and intermediate structures). As such, variations from the shapes of the illustrations as a result, for example, of manufacturing techniques and/or tolerances, are to be expected. Thus, exemplary embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, exemplary embodiments will be described in detail with reference to the accompanying drawings.

### Embodiment 1

FIG. 1 is a cross-sectional view illustrating a conductive structure in accordance with a first exemplary embodiment.

Referring to FIG. 1, a semiconductor pillar 16 is provided to protrude from a surface of a substrate 10. The semiconductor pillar 16 may include single-crystalline semiconductor material. The semiconductor pillar 16 may have a cylindrical shape or rectangular parallelepiped shape.

A hard mask pattern 18 is provided on the semiconductor pillar 16. The hard mask pattern 18 covers an upper surface of the semiconductor pillar 16. An upper surface of the hard mask pattern 18 may have an area greater than that of the upper surface of the semiconductor pillar 16.

A first conductive layer pattern 22a is provided to face a sidewall of the semiconductor pillar 16. The first conductive layer pattern 22a surrounds the sidewalls of the semiconductor pillar.

The first conductive layer pattern 22a may be formed to directly contact the sidewall of the semiconductor pillar 16. Alternatively, another layer may be interposed between the first conductive layer pattern 22a and the sidewall of the semiconductor pillar 16.

The first conductive layer pattern 22a may include a first portion and second portions. The first portion surrounds the sidewall of the semiconductor pillar 16. The second portions are folded from both sides of the first portion to face the substrate respectively. In this embodiment, the first conductive layer pattern 22a may be formed conformally on a lower surface of the hard mask pattern, the sidewall of the semiconductor pillar 16 and a portion of the surface of the substrate 10.

The second conductive layer pattern 24a is provided on the first conductive layer pattern 22a to face the sidewall of the pillar. The second conductive layer pattern 24a may have a shape filling a gap between the second portions included in the first conductive layer pattern 22a.

The second conductive layer pattern 24a may include a material having a resistance lower than the first conductive layer pattern 22a. The stacked structure of the first and second conductive layer patterns 22a and 24a may have a resistance lower than that of the stacked structure of only the first conductive layer pattern 22a.

As mentioned above, the semiconductor structure according to this embodiment has a stacked conductive structure where a pillar protruding from the substrate and conductive layer patterns of more than two layers formed laterally from the pillar are sequentially formed. The conductive structure facing the pillar may have a relatively low resistance.

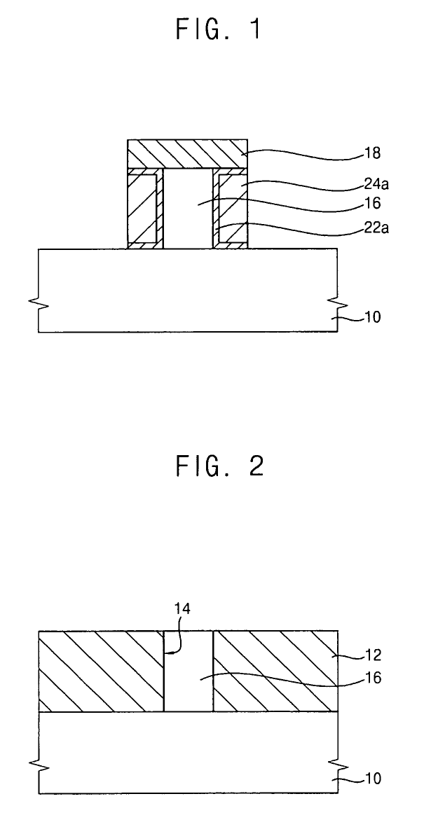

FIGS. 2 to 5 are cross-sectional views illustrating a method of manufacturing a conductive structure in accordance with a first exemplary embodiment.

Referring to FIG. 2, a pillar 16 including single-crystalline semiconductor material (hereinafter, referred to as “semiconductor pillar”) is formed on a substrate 10.

In an exemplary embodiment, a portion of the substrate 10 may be etched to form the semiconductor pillar 16. Alternatively, a mold layer 12 may be formed on the substrate 10, the mold layer 12 may partially etched to form an opening 14 in a region for the semiconductor pillar to be formed in the mold layer 12, and then, a semiconductor material may be grown in the opening 14 to form the semiconductor pillar 16.

In this embodiment, a semiconductor material may be grown to form the semiconductor pillar on the substrate 10. Hereinafter, a method of forming the semiconductor pillar will be described in detail.

First, a mold layer (not illustrated) is formed on the substrate 10. The mold layer may be formed using a layer to be etched easily by a wet etch process. For example, the mold layer may be formed using silicon oxide. A portion of the mold layer is etched to form a mold pattern 12 including an opening 14 formed therein. The substrate is exposed through a bottom surface of the opening 14. An amorphous silicon layer is deposited to completely fill the opening 14 and is planarized to form an amorphous silicon pattern in the opening 14. The amorphous silicon pattern undergoes phase transition to single-crystalline silicon, to form a single-crystalline silicon pattern. A thermal treatment may be performed using a laser to the single-crystalline silicon pattern. An upper surface of the single-crystalline silicon pattern is planarized to form the semiconductor pillar 16 including single-crystalline silicon.

As described above, the semiconductor pillar 16 may be formed by a laser-induced epitaxial growth process. Alternatively, the semiconductor pillar 16 may be formed by a selective epitaxial growth process using the surface of the substrate exposed through the bottom surface of the opening 14 as a seed.

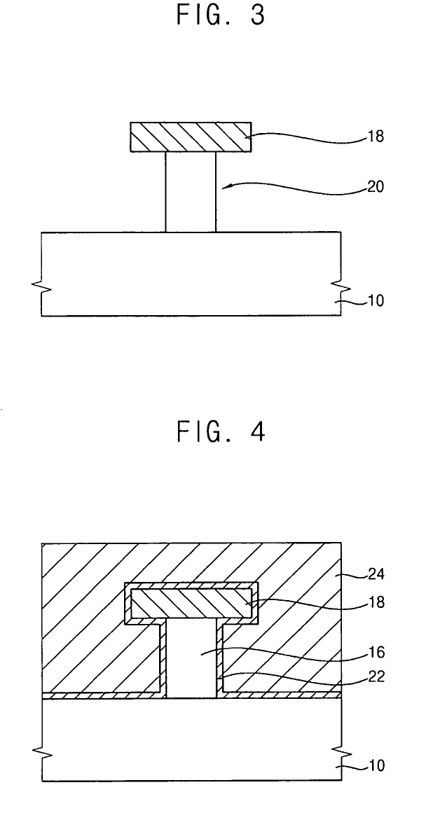

Referring to FIG. 3, a hard mask layer (not illustrated) is formed on the semiconductor pillar 16 and the mold pattern 12. A portion of the hard mask layer is etched to form a hard mask pattern 18 covering an upper surface of the semiconductor pillar 16. The hard mask pattern 18 has an area greater than that of the upper surface of the semiconductor pillar 16.

The hard mask pattern 18 is used as a mask for patterning a conductive structure that protrudes laterally from the semiconductor pillar 16. Accordingly, the hard mask pattern 18 covering the upper surface of the semiconductor pillar 16 protrudes by a width of the conductive structure from an edge of the semiconductor pillar 16.

The mold pattern 12 under the hard mask pattern 18 is completely removed. As the mold pattern 12 is removed to expose sidewalls of the semiconductor pillar 16, a gap 20 is formed under the hard mask pattern 18.

Referring to FIG. 4, a first conductor layer 22 is formed conformally on a bottom surface and an upper surface of the hard mask pattern 18, the sidewalls of the semiconductor pillar 16 and the surface of the substrate 10.

A second conductive layer 24 is formed on the first conductive layer 22. The second conductive layer 24 may be formed using a material having a resistance lower than the first conductive layer 22. The second conductive layer 24 is formed to completely fill the gap under the hard mask pattern 18.

For example, the first conductive layer 22 may be deposited using polysilicon and the second conductive layer 24 may be deposited using metal silicide or metal.

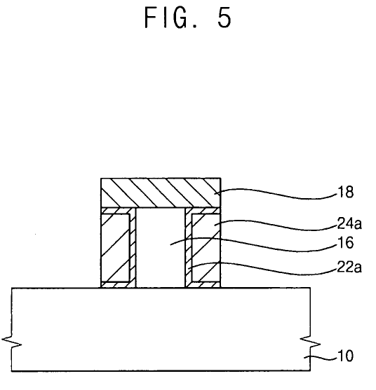

Referring to FIG. 5, the first and second conductive layers 22 and 24 are planarized to expose the upper surface of the hard mask pattern 18. Then, the second conductive layer 24 is etched using the hard mask pattern as an etching mask. The first conductive layer 22 is etched using the hard mask pattern as an etching mask. The etch process is performed to form first and second conductive layer patterns 22a and 24a that are sequentially stacked to face the sidewalls of the pillar.

Alternatively, the second conductive layer 24 may be anisotropically etched and then the first conductive layer 22 may be anisotropically etched to from the first and second conductive layer patterns 22a and 24a, without performing the planarization process.

### Embodiment 2

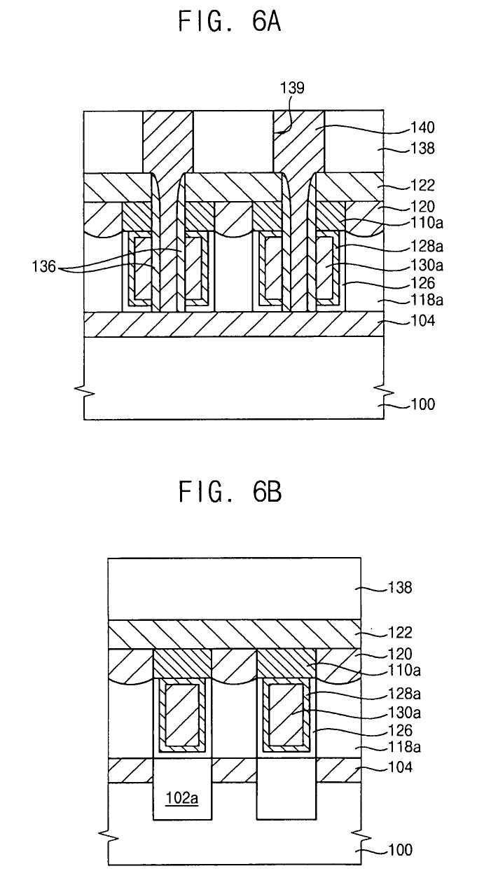

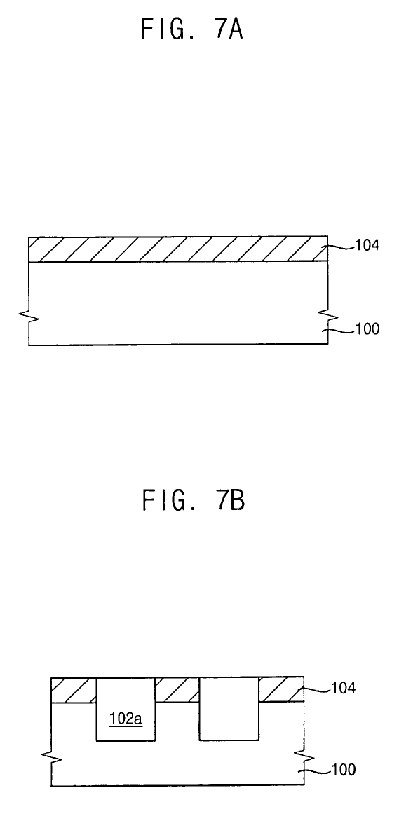

FIGS. 6A and 6B are cross-sectional views illustrating a vertical-type pillar transistor in accordance with a second exemplary embodiment. FIG. 6A is a cross-sectional view taken along a first direction where an active region extends. FIG. 6B is a cross-sectional view taken along a second direction perpendicular to the first direction.

Referring to FIGS. 6A and 6B, a substrate 100 having an active region and an isolation region is provided. For example, the substrate 100 may include single-crystalline silicon. Trenches are formed in the isolation region of the substrate and an isolation layer pattern 102a is formed in the trench. The active region and the isolation region have a linear shape extending in the first direction. The active regions and the isolation regions are arranged alternatively to one another.

A single-crystalline semiconductor pillar 118a is provided on the active region of the substrate 100. The semiconductor pillar 118a may include single-crystalline silicon. The semiconductor pillar 118a may include single-crystalline silicon formed by a laser-induced epitaxial growth process or a selective epitaxial growth process. For example, the semiconductor pillar 118a may include single-crystalline silicon formed by a laser-induced epitaxial growth process having a relatively low crystal defect. The semiconductor pillar 118a may have a cylindrical shape. Alternatively, the semiconductor pillar 118a may have a rectangular parallelepiped shape. A plurality of the semiconductor pillars 118a may be arranged at regular intervals.

A first hard mask pattern 110a is provided on an upper sidewall of the semiconductor pillar 118a. The first hard mask layer 110a extends in the second direction perpendicular to the first direction. The first hard mask layer 110a may have a shape surrounding the semiconductor pillar 118a arranged repeatedly in the second direction. The upper surface of the first hard mask pattern 110a may be coplanar with the upper surface of the semiconductor pillar 118a. The thickness of the first hard mask pattern 110a may be the same as the width of a source region of the transistor. The first hard mask pattern 110a may include silicon nitride.

A second hard mask pattern 122 is provided on the upper surfaces of the first hard mask pattern 110a and the semiconductor pillar 118a contacting the first hard mask pattern 110a. The first and second hard mask patterns 110a and 122 may include the same material. In this embodiment, the first and second hard mask pattern 110a and 122 may include silicon nitride.

A gate insulation layer 126 is provided on the sidewall of the semiconductor pillar 118a under the first hard mask pattern 110a. The gate insulation layer 126 may be formed conformally on a lower sidewall of the semiconductor pillar 118a and the surface of the substrate connected to the lower sidewall of the semiconductor pillar 118a. The gate insulation layer 126 may include silicon oxide formed by thermally oxidizing the sidewall of the semiconductor pillar 118a. The gate insulation layer 126 formed on the sidewall of the semiconductor pillar 118a may function as a gate insulation layer of a vertical-type pillar transistor. The gate insulation layer 126 formed on the surface of the substrate 100 may insulate the substrate from the gate electrode formed by a following process.

A first conductive layer pattern 128 is provided conformally on a surface of the gate insulation layer 126 and the lower surface of the first hard mask pattern 110a. The first conductive pattern 128a may include a first portion and second portions. The first portion faces the sidewall of the semiconductor pillar 118a. The second portions are folded from both sides of the first portion to face the substrate respectively. In here, a portion of the first conductive layer pattern 128a on the surface of the gate insulation layer 126 faces the sidewall of the semiconductor pillar 118a. The first conductive layer pattern 128a may include a material having a relatively excellent deposition characteristics with respect to the sidewall of the semiconductor pillar. For example, the first conductive layer pattern 128a may include polysilicon.

A second conductive layer pattern 130a is provided on the first conductive layer pattern 128a. The second conductive layer pattern 130a may have a shape filling a gap between the second portions included in the first conductive layer pattern 128a. The second conductive layer pattern 130a may have a linear shape extending to face the semiconductor pillars 118a arranged in the second direction.

The second conductive layer 130a may have a resistance lower than the first conductive layer 128. The second conductive layer 130a may include a metal silicide layer or a metal layer. For example, the stacked first and second conductive layer patterns 128a and 130a may have a structure where a polysilicon layer and a metal silicide layer are stacked laterally from the semiconductor pillar 118a.

The outer sidewalls of the first and second conductive layer patterns 128a and 130a and the outer sidewalls of the first and second hard mask patterns 110a and 122 may have a vertical inclination with respect to the surface of the substrate 100. The outer sidewalls of the first and second conductive layer patterns 128a and 130a and the outer sidewalls of the first and second hard mask patterns 110a and 122 may be even.

A first impurity region 104 is provided under the surface of the active region of the substrate 100 to be used as a source/drain. The first impurity region 104 may extend to a lower portion of the semiconductor pillar 118a by diffusion of impurities.

A second impurity region 120 is provided in an upper portion of the semiconductor pillar 118a. The second impurity region 120 may extend adjacent to the lower surface of the first hard mask pattern 110a.

A spacer 136 is provided on both sidewalls of the first and second conductive layer patterns 128a and 130a and the first and second hard mask patterns 110a and 122. The spacer 136 may include silicon nitride. The spacer 136 may protect the first and second conductive layer pattern 128a and 130a.

A first insulation interlayer 138 is provided to fill a gap between the spacers 136 and to cover the second hard mask pattern 122. The first insulation interlayer 138 may include silicon oxide.

A contact plug 140 is provided in the first insulation layer 138 to make contact with the substrate 100. The contact plug 140 may make contact with the surface of the substrate 100 between the spacers 136. The contact plug 140 makes contact with the first impurity region 104.

Since a gate electrode of a vertical-type pillar transistor according to this embodiment includes two or more conductive materials, the resistance of the gate electrode may be relatively very low. Accordingly, a vertical-type pillar transistor according to this embodiment may have a relatively rapid operating speed.

FIGS. 7A to 19B are cross-sectional views illustrating a method of manufacturing a vertical-type pillar transistor in accordance with a second exemplary embodiment. The A-figures of FIGS. 7A to 19B, that is, FIGS. 7A to 19A, are cross-sectional views taken along a first direction where an active region extends. The B-figures of FIGS. 7A to 19B, that is, FIGS. 7B to 19B, are cross-sectional views taken along a second direction perpendicular to the first direction.

Referring to FIGS. 7A and 7B, a substrate 100 including single-crystalline semiconductor material is prepared. The substrate 100 may include single-crystalline silicon.

A shallow trench isolation process is performed on the substrate 100 to form an isolation layer pattern 102a in an isolation region. In particular, a portion of the substrate 100 is etched to form trenches extending repeatedly in the first direction, and then an insulation layer is formed to fill the trenches, to form the isolation layer pattern 102a.

The substrate 100 is divided into the active region and the isolation region by forming the isolation layer pattern 102a. The active region and the isolation region have a linear shape extending in the first direction. The active regions and the isolation regions are arranged alternately to one another.

Impurities are implanted into the substrate 100 including the isolation layer pattern 102a formed therein to form a first impurity region 104. In this embodiment, n-type impurities may be implanted into the substrate to form the first impurity region 104.

Alternatively, the ion implantation process for forming the first impurity region 104 may be performed before forming the isolation layer pattern 102a. In this case, when the process of forming the isolation layer pattern 102a is performed, the first impurity region 104 is formed in the active region.

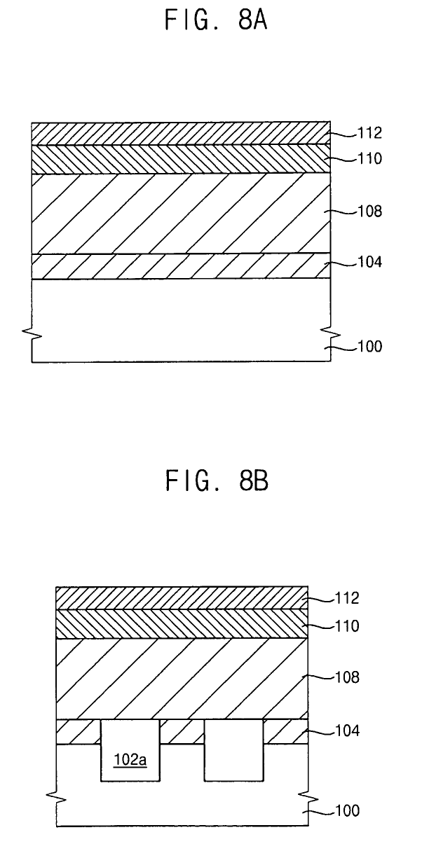

Referring to FIGS. 8A and 8B, a first sacrificial layer 108, a first hard mask layer 110 and a second sacrificial layer 112 are sequentially formed on the substrate 100.

The first sacrificial layer 108 may be formed using a material having an etch selectivity with respect to the first hard mask layer 110. When the first sacrificial layer 108 is removed, the first hard mask pattern 110 may not removed to remain. The second sacrificial layer 112 may be formed using the same material as first sacrificial layer 108. For example, the first hard mask layer 110 may be formed by depositing silicon nitride, and the first and second sacrificial layers 108 and 112 may be formed by depositing silicon oxide. The first and second sacrificial layers 108 and 112 may be formed using silicon oxide by a high density plasma chemical vapor deposition process.

The first sacrificial layer 108 may be a layer to define a region for a gate electrode to be formed. Therefore, the first sacrificial layer 108 may have a thickness the same as or greater than that of the gate electrode to be formed.

The first hard mask layer 110 may define a width of a second impurity region of a vertical-type pillar transistor.

The first sacrificial layer 108 and the first hard mask layer 110 may define a height of the semiconductor pillar. Accordingly, by controlling the height of the first sacrificial layer 108 and the first hard mask layer 110, the height of the semiconductor pillar may be controlled.

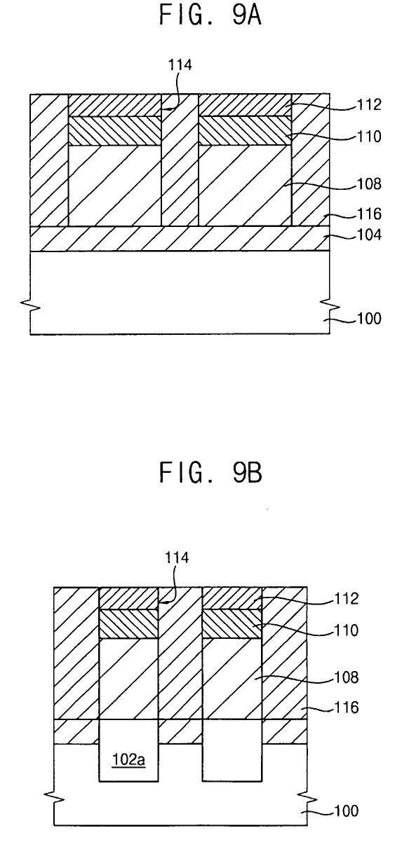

Referring to FIGS. 9A and 9B, a photoresist layer is coated on the second sacrificial layer 112, and then, is patterned to form a first photoresist pattern (not illustrated). The first photoresist pattern may selectively expose a region for the semiconductor pillar to be formed. The exposing portions of the first photoresist pattern are spaced apart from one another by a predetermined distance and are arranged repeatedly, facing the active region of the substrate 100.

The second sacrificial layer 112, the first hard mask layer 110, the first sacrificial layer 108 are sequentially etched using the first photoresist pattern as a mask to form a first opening 114. The first opening 114 may have a contact hole shape.

An amorphous silicon layer (not illustrated) is deposited to fill the first opening 114. The amorphous silicon layer may be deposited by a low pressure chemical vapor deposition process. In the process, the amorphous silicon layer may be doped with P-type impurities in-situ. Thus, a channel region of the vertical-type transistor may be doped with the impurities.

The amorphous silicon layer is planarized until an upper surface of the second sacrificial layer 112 is exposed, to form an amorphous silicon pattern 116.

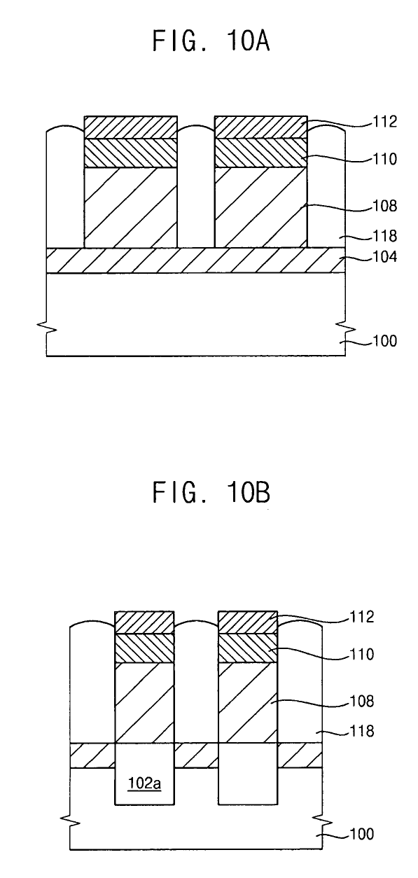

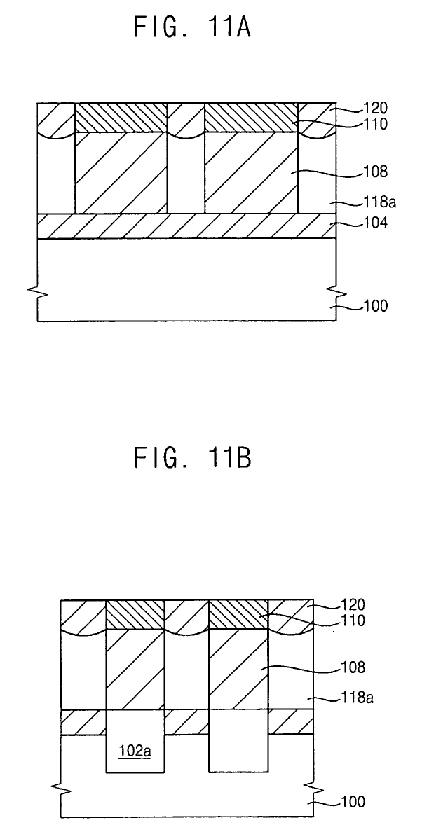

Referring to FIGS. 10A and 10B, the amorphous silicon pattern 116 is thermally treated to form a preliminary semiconductor pillar 118 including single-crystalline silicon.

The preliminary semiconductor pillar 118 may be formed by a laser-induced epitaxial growth (LEG) process or a solid phase epitaxy (SPE) process. For example, the thermal treatment process may be performed using a laser or a furnace.

In the LEG process, the laser used for the thermal treatment may have an energy density to completely melt the amorphous silicon pattern 116.

As a laser beam is irradiated to melt the amorphous silicon pattern 116, the amorphous silicon is changed from a solid phase to a liquid phase. The phase transition occurs from an upper surface of the amorphous silicon pattern 116 to an upper surface of the substrate 100 beneath a bottom surface of the first opening 114. For example, the laser beam may be irradiated at a temperature of about 1,410° C., the melting point of silicon.

Accordingly, the single crystal in the substrate 100 is used as a seed for the liquefied amorphous silicon pattern 116, and thus the crystal structure of the amorphous silicon pattern 116 is changed to single crystal structure. For example, an excimer laser as a kind of a gas laser may be used as a laser member for irradiating the laser beam. The laser member may irradiate the laser beam having a scanning type, and thus the laser beam may be irradiated in a relatively short time.

While the laser beam is irradiated, the substrate 100 may be heated together. Thus, when the amorphous silicon 116 undergoes a phase transition by the irradiation of the laser beam, the substrate 100 is heated together to thereby reduce a temperature gradient in a layer where the phase transition occurs. For example, when the laser beam is irradiated, the substrate 100 may be heated to about 400° C.

Thus, the laser beam is irradiated to the amorphous silicon pattern 116 to change the crystal structure of the amorphous silicon pattern 116 into single-crystalline silicon, to thereby form the preliminary semiconductor pillar 118. As the preliminary semiconductor pillar 118 is formed to shrink from the amorphous silicon pattern 116, the height of the preliminary semiconductor pillar 118 may become less than that of the amorphous silicon pattern 116.

Referring to FIGS. 11A and 11B, the preliminary semiconductor pillar 118 and the second sacrificial layer 112 are planarized to expose the first hard mask layer 110. Thus, the second sacrificial layer 112 may be removed completely by the planarization process and a semiconductor pillar 118a having an even upper surface may be formed from the preliminary semiconductor pillar 118. The upper surface of the semiconductor pillar 118a may be coplanar with an upper surface of the first hard mask layer 110. The semiconductor pillars 118a having isolated shapes may be arranged at regular intervals.

Then, impurities may be implanted into the upper surface of the semiconductor pillar 118a to form a second impurity region 120. In this embodiment, n-type impurities may be implanted to form the second impurity region 120.

The second impurity region 120 may extend adjacent to a lower surface of the first hard mask layer 110. Therefore, by controlling the thickness of the first hard mask layer 110, the second impurity region 120 may be controlled to be positioned.

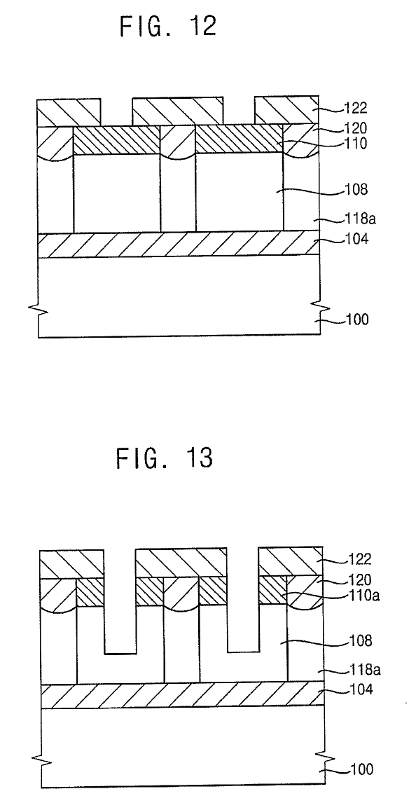

Referring to FIG. 12, a second hard mask layer (not illustrated) is formed on the first hard mask layer 110 and the semiconductor pillar 118. The second hard mask layer may be formed using the same material as the first hard mask layer 110. For example, the second hard mask layer may be formed by depositing silicon nitride.

A photoresist layer is formed on the second hard mask layer and then is patterned to form a second photoresist pattern (not illustrated) having a linear shape. The second photoresist pattern may have a linear shape extending in the second direction perpendicular to the first direction. The second photoresist pattern covers the semiconductor pillar 118a. The farther a portion of the second photoresist pattern protrudes from the circumference of the semiconductor pillar 118, the greater is the thickness of the gate electrode to be formed on sidewalls of the semiconductor pillar 118a.

The second hard mask layer is anisotropically etched using the second photoresist pattern as an etching mask to form a second hard mask pattern 122.

Referring to FIG. 13, the first hard mask layer 110 under the second hard mask pattern 122 is etched to form a first hard mask pattern 110a. The first hard mask pattern 110a is positioned under the second hard mask pattern 122 to surrounds upper sidewalls of the semiconductor pillar 118a

In this embodiment, when the first and second hard mask layers include the same material, the first and second hard mask layers may be etched at one time by the etch process to form the first and second hard mask patterns 110a and 122.

Then, the first sacrificial layer 108 is partially or completely removed by an anisotropic etch process. Alternatively, the process of anisotropically etching the first sacrificial layer 108 may be omitted. In this case, the first sacrificial layer 108 may remain under the first hard mask pattern 110a.

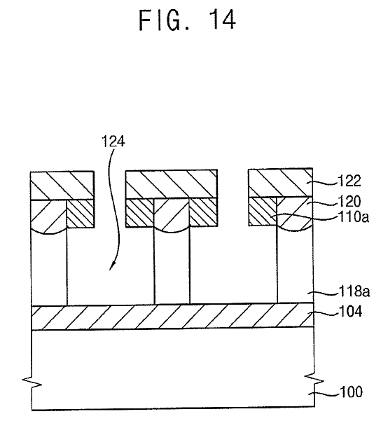

Referring to FIG. 14, the first sacrificial layer pattern 108 is removed by an isotropic etch process.

By performing the etch process, a gap 124 is formed under the first hard mask pattern 110a and between the first hard mask patterns 110a. That is, the first hard mask pattern 110a may surround the sidewall of the semiconductor pillar 118a without being supported by an underlying layer. The first hard mask pattern 110a may have a linear shape surrounding the semiconductor pillars 118a arranged in the second direction.

Accordingly, the sidewall of the semiconductor pillar 118a is partially exposed under the first hard mask pattern 110a. A gate is formed on the exposed sidewall of the semiconductor pillar 118a by a following process. By the following process, the gate is formed to fill a space defined by the first sidewall of the semiconductor pillar 118a, a lower surface of the first hard mask pattern 110a and the surface of the substrate 100.

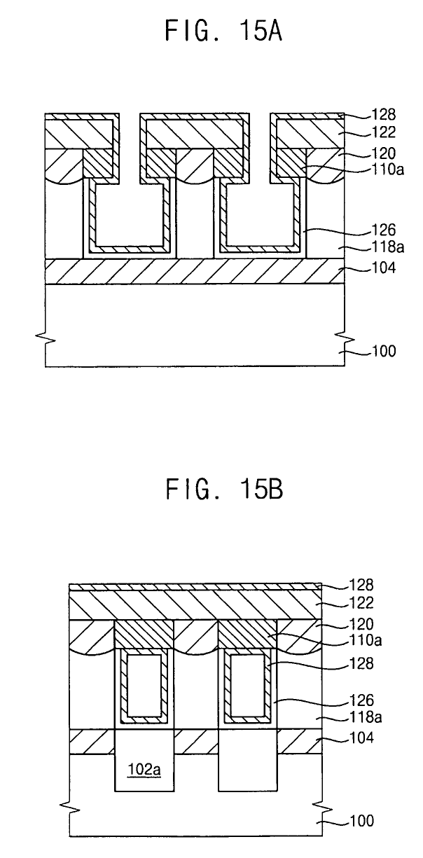

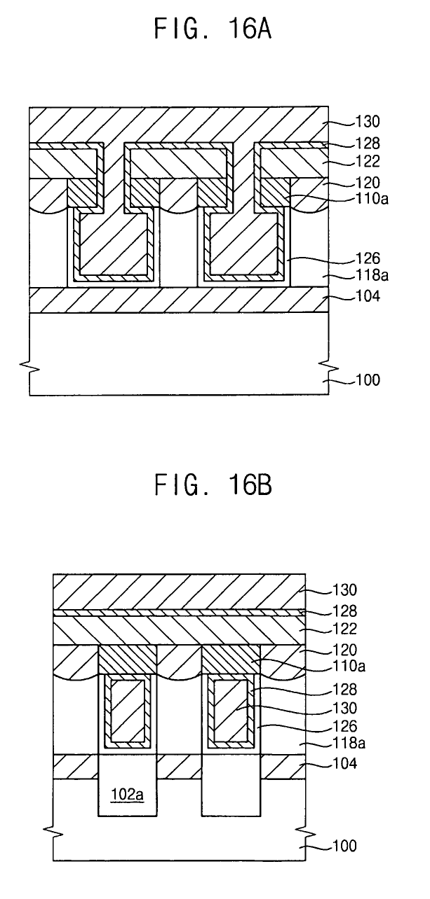

Referring to FIGS. 15A and 15B, the exposed sidewall of the semiconductor pillar 118a and the exposed surface of the substrate 100 are thermally oxidized to form a gate insulation layer 126. The gate insulation layer 126 may be formed using silicon oxide by a thermal oxidation process.

The gate insulation layer 126 formed on the sidewall of the semiconductor pillar 118a may function as a gate insulation layer of the vertical-type pillar transistor. The gate insulation layer 126 formed on the surface of the substrate 100 may insulate the substrate and the gate electrode formed by a following process each other.

A first conductive layer 128 is formed conformally on surfaces of the second hard mask pattern 122, the first hard mask pattern 110a and the gate insulation layer 126. The first conductive layer 128 may be formed using a polysilicon layer having excellent step coverage characteristics. When the process of depositing the polysilicon layer is performed, n-type impurities may be doped in-situ.

The first conductive layer 128 may not completely fill the gap between the second hard mask patterns 122. For example, the first conductive layer 128 may have a thickness less than half of the width of the gap between the second hard mask patterns 122.

Referring to FIGS. 16A and 16B, a second conductive layer 130 is formed on the first conductive layer 128 to completely fill the gaps between the hard mask patterns 122. The second conductive layer 130 may be formed using a material having a resistance lower than the first conductive layer 128. The second conductive layer 130 may include a metal silicide layer or a metal layer. For example, the second conductive layer 130 may be formed by depositing tungsten silicide through a CVD process.

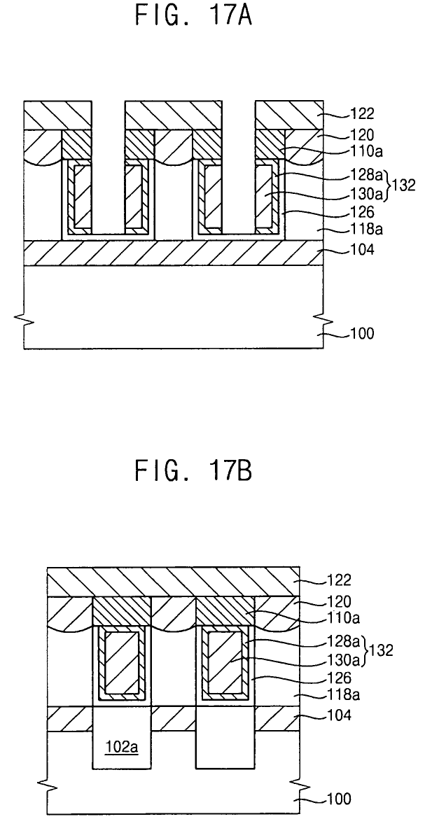

Referring to FIGS. 17A and 17B, the first and second conductive layers 128 and 130 on an upper portion of the second hard mask pattern 122 and between the second hard mask patterns 122 are removed using the second hard mask pattern as an etching mask to form first and second conductive layer patterns 128a and 130a.

In particular, the second conductive layer 130 on the second hard mask pattern 122 is completely removed by an anisotropic etch process. Then, the second conductive layer 130 between the second hard mask patterns 122 is removed by an anisotropic etch process to form the second conductive layer pattern 130a. The first conductive layer 128 on the second hard mask pattern 122 is completely removed by an anisotropic process. Then, the first conductive layer 128 between the second hard mask patterns 122 is removed by an anisotropic etch process to form the first conductive layer pattern 128a.

Alternatively, if the first and second conductive layers 128 and 130 can be etched by the same etching gas, the first and second conductive layers 128 and 130 may be anisotropically etched using the second hard mask pattern 122 as an etching mask until the gate insulation layer 126 is exposed, to form the first and second conductive layer patterns 128a and 130a.

In another exemplary embodiment, the first and second conductive layers 128 and 130 may be partially removed by a planarization process until the upper surface of the second hard mask pattern 122 is exposed. Then, the first and second conductive layers 128 and 130 may be etched using the second hard mask pattern 122 as an etching mask to form the first and second conductive layer patterns 128a and 130a.

The second hard mask pattern 122 is used as an etching mask to form the first and second conductive layer pattern 128a and 130a. Accordingly, outer sidewalls of the first conductive layer pattern 128a, the second conductive layer pattern 130a, the first hard mask pattern 110a and the second hard mask pattern 122 may be formed to be even. Further, because the first and second conductive layer patterns 128a and 130a are formed by an anisotropic etch process, the outer sidewalls of the first and second conductive layer patterns 128a and 130a and the outer sidewalls of the first and second hard mask patterns 110a and 122 may have a vertical inclination with respect to the surface of the substrate 100.

The first conductive pattern 128a may include a first portion and second portions. The first portion faces the sidewall of the semiconductor pillar 118a. The second portions are folded from both sides of the first portion to face the substrate respectively. The second conductive layer pattern 130a may have a shape filling a gap between the second portions included in the first conductive layer pattern 128a. The second conductive layer pattern 130a may have a linear shape extending in the second direction.

The first and second conductive layer patterns 128a and 130a may be used as a gate electrode 132 of the vertical-type pillar transistor.

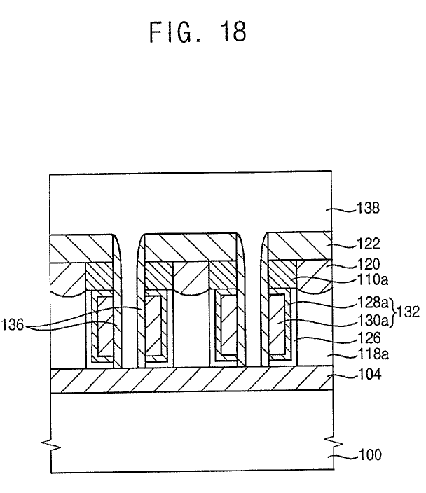

Referring to FIG. 18, an insulation layer for a spacer (not illustrated) is formed on surfaces of the gate electrode 132, the first hard mask pattern 110a and the second hard mask pattern 122 and the substrate 100. The insulation layer for a spacer may be formed by depositing silicon nitride.

The insulation layer for a spacer is anisotropically etched to form a spacer 136 on both sidewalls of the gate electrode 132 and the first and second hard mask patterns 110a and 122.

A first insulation interlayer 138 is formed to fill a gap between the spacers 136 and to cover the second hard mask pattern 122. The first insulation interlayer 138 may be formed by depositing silicon oxide.

After forming the first insulation interlayer 138, a planarization process may be further performed to planarize an upper surface of the first insulation interlayer 138.

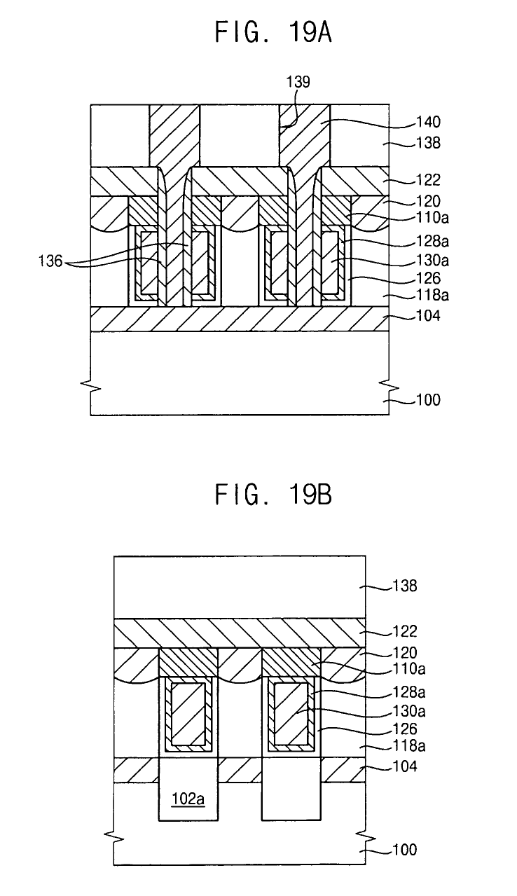

Referring to FIGS. 19A and 19B, the first insulation interlayer 138 is partially anisotropically etched to form a contact hole 139 exposing the active region of the substrate 100. The contact hole 139 may be formed to expose both the active region and the isolation region adjacent to the semiconductor pillar 118a. The contact hole 139 may be formed by a self-align etch process using etch selectivity between the spacer 136 and the first insulation interlayer 138.

A conductive layer (not illustrated) is formed to fill the contact hole 139. For example, the conductive layer may be formed using polysilicon doped with impurities. Alternatively, the conductive layer may be formed using metal. The conductive layer is planarized until the first insulation interlayer 128 is exposed, to form a contact plug 140. An electric signal may be applied to the first impurity region 104 of the vertical-type pillar transistor through the contact plug 140.

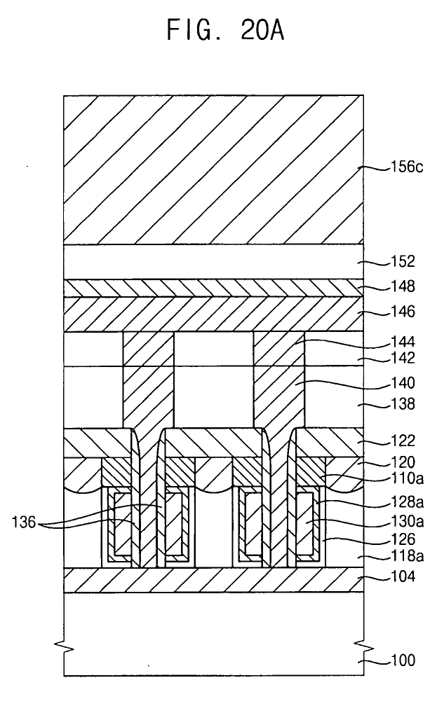

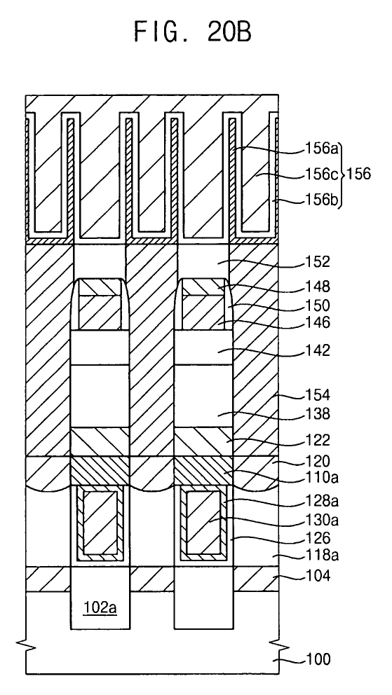

FIGS. 20A and 20B are cross-section views illustrating a DRAM device including a vertical-type pillar transistor in accordance with a second exemplary embodiment.

A DRAM device according to the present embodiment are substantially the same as in Embodiment 2 except that a capacitor is further provided. That is, a capacitor is further provided to be electrically connected to a second impurity region of a vertical-type pillar transistor.

Referring to FIGS. 20A and 20B, a second insulation interlayer 142 is provided to cover the vertical-type pillar transistor in Embodiment 2. A direct contact 144 is provided in the second insulation interlayer 142 to make contact with a portion of the contact plug 140. That is, the direct contact 144 may be arranged to move left or right in the second direction from an upper surface of the contact plug 140 such that the direct contact 144 partially make contact with the upper surface of the contact plug 140 not to cover the entire upper surface of the contact plug 140.

A bit line 146 is provided on the direct contact 144. The bit line 146 is electrically connected to the contact plug 140 by the direct contact 144. The bit line 146 may extend in the first direction. The bit line may be arranged to partially make contact with an upper surface of the direct contact without covering the entire upper surface of the direct contact 144.

A third hard mask pattern 148 may be further provided on the upper surface of the bit line 146 and a second spacer 150 may be further provided on a sidewall of the bit line 146.

A third insulation interlayer 152 is provided to fill a gap between the bit lines 146 and to cover the bit line 146.

A second contact plug 154 is provided to penetrate the third and second insulation interlayers 152 and 142 to be connected to the upper surface of the semiconductor pillar 118a. The second contact plug 154 is positioned between the bit lines 146. In here, the second contact plug 154 makes contact with the upper surface of the semiconductor pillar 118a, being insulated from the bit lines 146. That is, the second contact plug 154 is electrically connected to the second impurity region 120.

The second contact plug 154 may include metal material. Alternatively, the second contact plug 154 may include polysilicon.

A capacitor 156 is provided on the second contact plug 154. In this embodiment, the capacitor may include a cylindrical lower electrode 156a, a dielectric layer 156b and an upper electrode 156c. Alternatively, the capacitor may have a stacked structure where a lower electrode having an even upper surface, a dielectric layer and an upper electrode are sequentially stacked.

If the line and space of each pattern in the DRAM device formed through a photolithography process width have a critical width (F) respectively, each unit cell of the DRAM device may be provided in an area of 4F². Further, as a resistance of the gate electrode of the vertical-type pillar transistor is reduced, the DRAM device may be highly integrated and the operating speed thereof may be increased.

After forming the vertical-type pillar transistor in Embodiment 2, the DRAM device in FIGS. 20A and 20B is manufactured by performing following processes. Hereinafter, processes after forming the vertical-type pillar transistor in Embodiment 2 will be described.

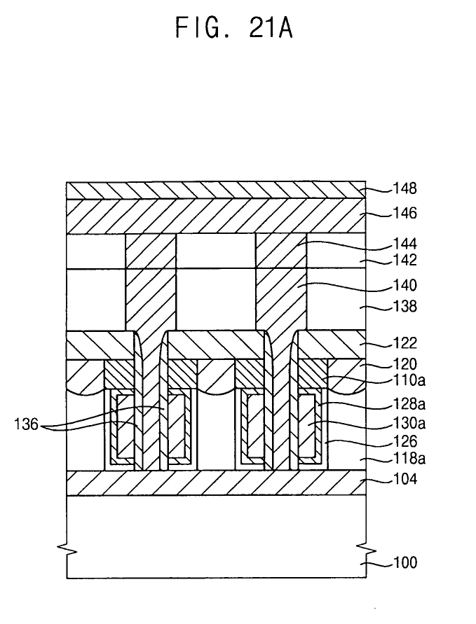

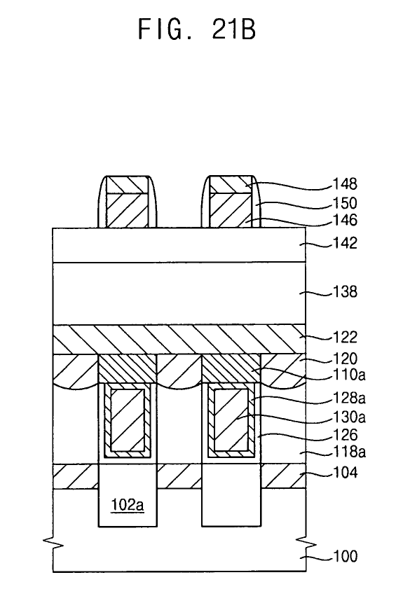

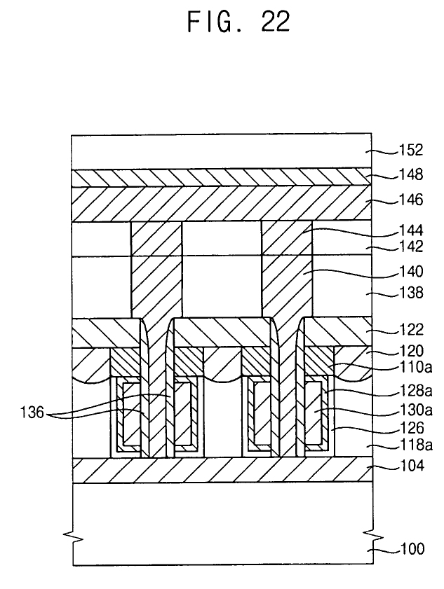

FIGS. 21A, 21B and 22 are cross-sectional views illustrating a method of manufacturing a DRAM device including a vertical-type pillar transistor in accordance with a second exemplary embodiment.

Referring to FIGS. 21A and 21B, a second insulation interlayer 142 is formed on the contact plug 140 and the first insulation interlayer 138. The second insulation interlayer 142 may be formed by depositing silicon oxide.

The second insulation interlayer 142 is partially etched to form a second contact hole that partially exposes the contact plug 140. The second contact hole may be positioned at a position between the semiconductor pillars 118a that are arranged diagonally to each other.

After a conductive layer is deposited to fill the second contact hole, the conductive layer is planarized until the second insulation interlayer 142 is exposed, to form a direct contact 144.

The contact plug 140 is arranged to move left or right in the second direction from the position facing the semiconductor pillar 118a, and the direct contact 144 is arranged to move in the second direction from the position facing the contact plug 140 such that the direct contact 144 is further from the semiconductor pillar 118a than the contact plug 140. Accordingly, upper surfaces of the direct contacts 144 may be repeatedly arranged between the semiconductor pillars 118a.

A conductive layer for a bit line (not illustrated) is formed on the direct contact 144. The conductive layer for a bit line may be formed using polysilicon, metal, metal silicide, etc. These may be used alone or in a combination.

A third hard mask pattern 148 is formed on the conductive layer for a bit line. A silicon nitride layer may be deposited and patterned to form the third hard mask pattern 148. The third hard mask pattern 148 may have a linear shape extending in the first direction to face the direct contact.

The conductive layer for a bit line may be anisotropically etched using the third hard mask pattern 148 as an etching mask to form a bit line 148. The bit line 148 is positioned between the semiconductor pillars 118a that are arranged parallel with the first direction.

An insulation layer for a spacer (not illustrated) is formed on surfaces of the bit line 146, the third hard mask pattern 148 and the second insulation interlayer 142. The insulation for a spacer may be anisotropically etched to form a second spacer 150 on both sides of the bit line 146 and the third hard mask pattern 148. The second spacer 150 may include silicon nitride.

Referring to FIG. 22, a third insulation interlayer 152 is formed to fill a gap between the bit lines 146 and to cover the bit lines 146. The third insulation interlayer 152 may be formed using silicon oxide.

Portions of the third, second and first insulation interlayers 152, 142 and 138 between the bit lines 146 may be anisotropically etched to form contact holes that expose the upper surfaces of the semiconductor pillars 118a respectively. The anisotropic etch process may be performed through a self-aligned contact process using etch selectivity of the second spacer 150 and the third insulation interlayer 152.

As illustrated in FIGS. 20A and 20B, a conductive material is formed to fill the contact hole and is planarized until the third insulation interlayer 152 is exposed, to form a second contact plug 154. The conductive material may include metal. As the conductive material includes metal, the resistance of the second contact plug 154 may be reduced. Alternatively, the conductive material may include polysilicon.

A capacitor 156 is formed to make contact with the second contact plug 154. In this embodiment, the capacitor 156 may include a cylindrical lower electrode 156a, a dielectric layer 156b and an upper electrode 156c.

Hereinafter, processes of forming the cylindrical capacitor will be described.

An etch stop layer (not illustrated) is formed to cover the third insulation interlayer 152 and the second contact plug 154. The etch stop layer may be formed by depositing silicon nitride by a chemical vapor deposition process.

A mold layer is formed on the etch stop layer. The mold layer may be formed using a material having etch selectivity with respect to the etch stop layer. The mold layer may be formed by depositing silicon oxide.

The mold layer and the etch stop layer are partially etched by a photolithography process to form openings that expose the upper surfaces of the second contact plug 154 respectively. The opening may have a contact hole shape.

A lower electrode layer is formed conformally in the opening. The lower electrode layer may be formed using polysilicon. Alternatively, the lower electrode layer may include metal. For example, the lower electrode layer may include titanium nitride, titanium, tantalum nitride, tantalum, etc.

A sacrificial layer is formed to fill the opening where the lower electrode layer is formed. The sacrificial layer may include the same material as the mold layer. Alternatively, the sacrificial layer may include an organic material such as photoresist.

The sacrificial layer and the lower electrode layer are planarized until an upper surface of the mold layer is exposed. Accordingly, the lower electrode on the mold layer is removed by the planarization process to form a lower electrode 156a having a cylindrical shape.

Then, the mold layer and the sacrificial layer are removed to expose a surface of the lower electrode 156a. The mold layer and the sacrificial layer may be removed by a wet etch process using an etching solution. When the sacrificial layer includes silicon oxide the same as the mold layer, the mold layer and the sacrificial layer may be removed using a LAL solution, a SC1 (standard clean 1) solution or a diluted hydrofluoric acid solution in the range of about 100:1 to about 400:1. The LAL solution is a mixed solution of ammonium fluoride and hydrofluoric acid, the SC1 solution is a mixed solution of ammonium hydroxide and hydrogen peroxide, and these mixed solutions are widely used as a cleaning solution in a semiconductor manufacture process.

A dielectric layer 156b and an upper electrode 156c are formed on the lower electrode 156a.

Alternatively, although it is not in the figures, the capacitor 156 may be a stacked structure of a lower electrode, a dielectric layer and an upper electrode having an even upper surface respectively. The lower electrode layer, the dielectric layer and the upper electrode layer may be stacked on one another, and sequentially patterned to form the stack type capacitor.

### Embodiment 3

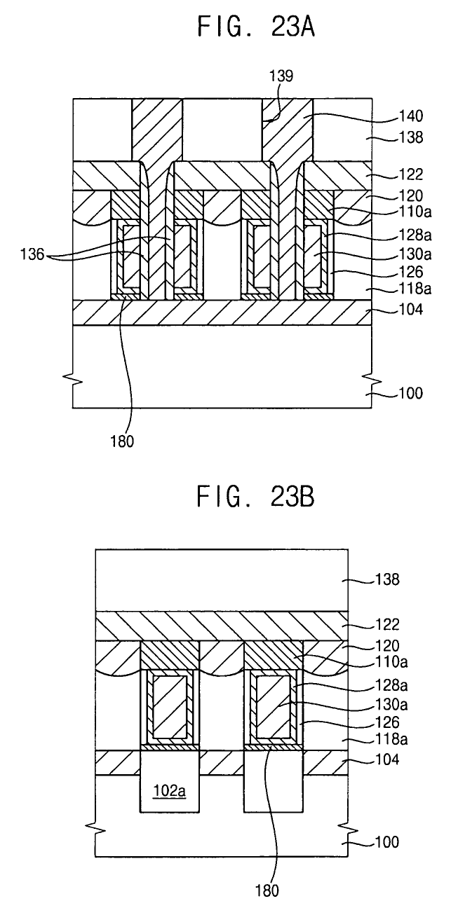

FIGS. 23A and 23B are cross-sectional views illustrating a vertical-type transistor in accordance with a third exemplary embodiment.

As illustrated in FIGS. 23A and 23B, a vertical-type pillar transistor according to the present embodiment are substantially the same as in Embodiment 1 except that an insulation layer including a material different from a gate insulation layer is provided between a substrate and a gate electrode.

The vertical-type pillar transistor according to the present embodiment may be manufactured by the same or like processes as those described in Embodiment 2 and any further repetitive description concerning the above processes will be omitted.

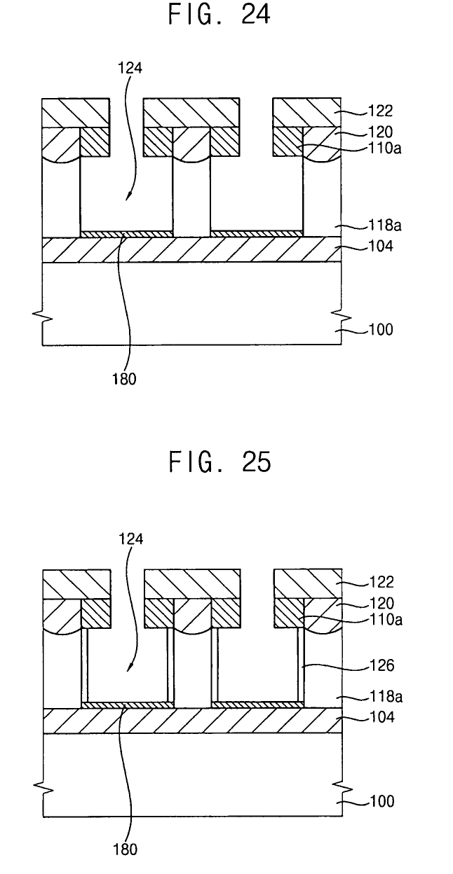

FIGS. 24 and 25 are cross-sectional views illustrating a method of manufacturing a vertical-type pillar transistor in accordance with a third exemplary embodiment.

First, the same processes as described with reference to FIGS. 7A and 7B are performed to define the active region and the isolation region in the substrate 100.

Then, an insulation layer, a first sacrificial layer, a first hard mask layer and a second sacrificial layer are sequentially formed on the substrate 100. The insulation layer may be formed using a material having etch selectivity the same as the first sacrificial layer. The insulation layer may be formed by depositing silicon nitride. The first sacrificial layer, the first hard mask layer and the second sacrificial layer may be formed by the same or like processes as explained in Embodiment 2.

The same processes as described with reference to FIGS. 9A to 14 are performed on the substrate. Thus, as illustrated in FIG. 23, the sidewall of the semiconductor pillar 118a is exposed while the insulation layer 180 remains on the surface of the substrate 100 so that the surface of the substrate 100 is not exposed.

Referring to FIG. 24, the exposed sidewall of the semiconductor pillar 118a is thermally oxidized to form a gate insulation layer 126. That is, the gate insulation layer 126 may include silicon oxide formed by a thermal oxidation process. In this embodiment, the gate insulation layer 126 is formed only on the sidewall of the semiconductor pillar 118a.

Then, the same or like processes as described with reference to FIGS. 15A to 19B are performed to complete the vertical-type pillar transistor in FIGS. 23A and 23B.

### Embodiment 4

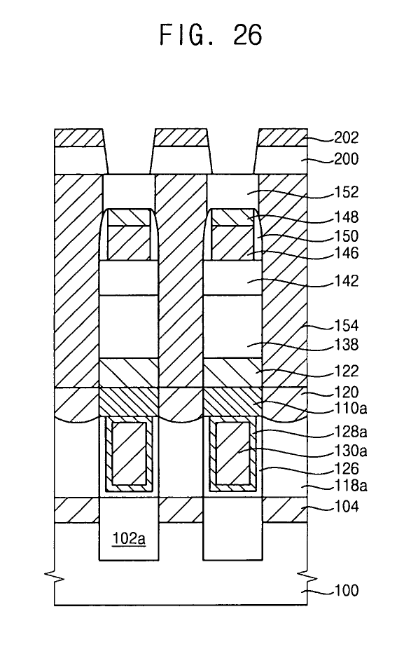

FIG. 26 is a cross-sectional view illustrating a memory device including a vertical-type pillar transistor in accordance with a fourth exemplary embodiment.

A vertical-type pillar transistor, a bit line and a contact plug of a memory device according to the present embodiment are substantially the same as the DRAM device in FIGS. 20A and 20B. However, unlike the DRAM device in FIGS. 20A and 20B, a phase changeable structure is provided on the second contact plug.

The phase changeable structure has a staked structure of a phase changeable layer pattern 200 and an upper electrode 202. For example, the upper electrode 202 may include metal. For example, the upper electrode 202 may include tungsten, titanium, titanium nitride, tantalum, tantalum nitride, molybdenum nitride, niobium nitride, titanium silicon nitride, aluminum, titanium aluminum nitride, titanium boron nitride, zirconium aluminum nitride, molybdenum silicon nitride, tungsten boron nitride, zirconium aluminum nitride, molybdenum silicon nitride, molybdenum aluminum nitride, tantalum silicon nitride, tantalum aluminum nitride. These may be used alone or in a combination thereof.

The phase changeable layer pattern 200 may include a chalcogenide. For example, the phase changeable layer pattern 200 may include germanium, antimony and tellurium. In this case, the contact plug may be provided as a lower electrode.

A mask pattern (not illustrated) is provided on the upper electrode 202.

When a specific current is applied to the phase changeable layer pattern 200 by a voltage difference between the upper electrode 202 and the second contact plug 154 provided as the lower electrode, a phase of the phase changeable layer pattern 200 is changed from a single-crystalline phase having a relatively low resistance to an amorphous phase having a relatively high resistance. Additionally, when the current applied to the phase changeable layer pattern 200 is decreased or removed, the phase of the phase changeable layer pattern 200 is changed from an amorphous phase to a single-crystalline phase. Thus, as the phase of the phase changeable layer pattern 200 is changed, the phase changeable structure including the lower electrode, the phase changeable layer pattern 200 and the upper electrode 202 may function as a switch.

After performing the processes of forming the DRAM device in Embodiment 2, the phase changeable structure may be formed to make contact with the second contact plug to manufacture a memory device in FIG. 26.

In particular, the processes described with reference to FIGS. 21A to 22B are performed to form the structure in FIGS. 22A and 22B. Then, processes for forming a phase changeable structure may be performed. Hereinafter, the processes for forming the phase changeable structure will be described.

A phase changeable layer is formed to cover the third insulation interlayer 152 and the second contact plug 154. The phase changeable layer may include a chalcogenide. The chalcogenide may include germanium (Ge), antimony (Sb) and tellurium (Te).

An upper electrode layer is formed on the phase changeable layer. The upper electrode layer may include metal. For example, the upper electrode layer may include tungsten, titanium, titanium nitride, tantalum, tantalum nitride, molybdenum nitride, niobium nitride, titanium silicon nitride, aluminum, titanium aluminum nitride, titanium boron nitride, zirconium aluminum nitride, molybdenum silicon nitride, tungsten boron nitride, zirconium aluminum nitride, molybdenum silicon nitride, molybdenum aluminum nitride, tantalum silicon nitride, tantalum aluminum nitride. These may be used alone or in a combination thereof.

A mask pattern is formed on the upper electrode layer. The mask pattern may include silicon nitride or silicon oxide.

The upper electrode layer and the phase changeable layer are etched using the mask pattern to form the phase changeable layer pattern 200 and the upper electrode 202 having an isolated shape to be connected to the second contact plug 154.

Although it is not illustrated in the figures, a magnetic structure may be provided on an upper surface of the contact plug in Embodiment 1 to manufacture a memory device in accordance with another exemplary embodiment. The magnetic structure may include a magnetoresistive tunnel junction (MJT) structure. The magnetic structure may include a tunnel junction of a first ferromagnetic layer, a tunneling barrier layer and a second ferromagnetic layer. Accordingly, data may be stored in the magnetic structure.

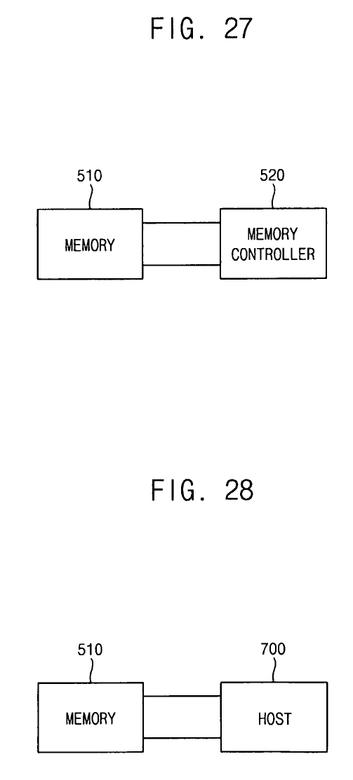

FIG. 27 illustrates another embodiment.

As illustrated in FIG. 27, this embodiment includes a memory 510 connected to a memory controller 520. The memory 510 may be the memory device described above. However, the memory 510 may be any memory architecture having the structures according to embodiments of the present invention. The memory controller 520 supplies the input signals for controlling operation of the memory 510. For example, the memory controller 520 supplies the command CMD and address signals, I/O signals, etc. It will be appreciated that the memory controller 520 may control the memory 510 based on received signals.

FIG. 28 illustrates yet another embodiment.

The memory 510 may be connected with a host system 700. The memory 510 may be any memory architecture having the structures according to embodiments of the present invention. The host system 700 may include an electric product such as a personal computer, digital camera, mobile application, game machine, communication equipment, etc. The host system 700 supplies the input signals for controlling operation of the memory 510. The memory 510 is used as a date storage medium.

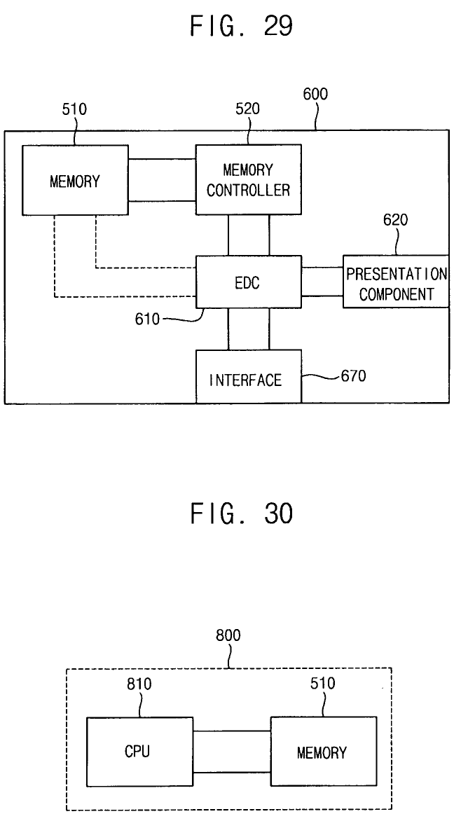

FIG. 29 illustrates a further embodiment. This embodiment represents a portable device 600. The portable device 600 may be an MP3 player, video player, combination video and audio player, etc. As illustrated, the portable device 600 includes the memory 510 and memory controller 520. The memory 510 may be any memory architecture having the structures according to embodiments of the present invention. The portable device 600 may also includes an encoder and decoder 610, a presentation component 620 and an interface 630. Data (video, audio, etc.) is input to and output from the memory 510 via the memory controller 520 by an encoder and decoder (EDC) 610.

FIG. 30 illustrates a still further embodiment of the present invention. As illustrated, the memory 510 may be connected to a central processing unit (CPU) 810 within a computer system 800. For example, the computer system 800 may be a personal computer, personal data assistant, etc. The memory 510 may be directly connected with the CPU 810, connected via bus, etc. The memory 510 may be any memory architecture having the structures according to embodiments of the present invention. It will be appreciated, that FIG. 33 does not illustrate the full complement of components that may be included within a computer system 800 for the sake of clarity.

As described above, a vertical-type transistor in accordance with some exemplary embodiments may be used as a selection transistor for various memory devices. Further, a vertical-type transistor in accordance with some exemplary embodiments may be positively applied for a semiconductor device to be highly integrated and having a relatively rapid operating speed.

The foregoing is illustrative of exemplary embodiments and is not to be construed as limiting thereof. Although a few exemplary embodiments have been described, those skilled in the art will readily appreciate that many modifications are possible in the exemplary embodiments without materially departing from the novel teachings and advantages of the present invention. Accordingly, all such modifications are intended to be included within the scope of the present invention as defined in the claims. In the claims, means-plus-function clauses are intended to cover the structures described herein as performing the recited function and not only structural equivalents but also equivalent structures. Therefore, it is to be understood that the foregoing is illustrative of various exemplary embodiments and is not to be construed as limited to the specific exemplary embodiments disclosed, and that modifications to the disclosed exemplary embodiments, as well as other exemplary embodiments, are intended to be included within the scope of the appended claims.

1. A conductive structure, comprising:
a pillar provided on a substrate;
a first conductive layer pattern provided on a sidewall of the pillar, at least a portion of the first conductive layer pattern facing the sidewall of the pillar,
a second conductive layer pattern provided on a surface of the first conductive layer pattern, the second conductive layer pattern facing the sidewall of the pillar; and
a hard mask pattern covering upper surfaces of the first conductive layer pattern and the pillar.

2. The conductive structure of claim 1, further comprising an insulation layer pattern making contact with the sidewall of the pillar.

3. The conductive structure of claim 1, wherein the first conductive layer pattern comprises a first portion facing the sidewall of the pillar and second portions that are folded from both sides of the first portion to face the substrate respectively.

4. The conductive structure of claim 3, wherein the second conductive layer pattern has a shape filling a gap between the second portions included in the first conductive layer pattern.

5. A vertical-type pillar transistor, comprising:
a single-crystalline semiconductor pillar provided on a substrate;
a gate insulation layer provided on a sidewall of the single-crystalline semiconductor pillar and a portion of the substrate;
a first conductive layer pattern provided on a surface of the gate insulation layer pattern, at least a portion of the first conductive layer pattern facing the sidewall of the pillar;
a second conductive layer pattern provided on a surface of the first conductive layer pattern, the second conductive layer pattern facing the sidewall of the pillar;
a hard mask pattern covering upper surfaces of the first conductive layer pattern and the single-crystalline semiconductor pillar; and
an impurity region provided under a surface of the substrate adjacent to the single-crystalline semiconductor pillar.

6. The vertical-type pillar transistor of claim 5, wherein the gate insulation layer has a folded shape at a contact portion between the substrate and the pillar to insulate the first conductive layer pattern from the substrate.

7. The vertical-type pillar transistor of claim 5, wherein the gate insulation layer comprises thermal oxide formed by a thermal oxidation process.

8. The vertical-type pillar transistor of claim 7, wherein the first conductive layer pattern comprises a first portion facing the sidewall of the pillar and second portions that are folded from both sides of the first portion to face the substrate respectively.

9. The vertical-type pillar transistor of claim 8, wherein the second conductive layer pattern has a shape filling a gap between the second portions included in the first conductive layer pattern.

10. The vertical-type pillar transistor of claim 8, wherein a plurality of the single-crystalline semiconductor pillars is arranged at regular intervals, and the second conductive layer pattern extends to face the sidewalls of the single-crystalline semiconductor pillars arranged in a direction.

11. The vertical-type pillar transistor of claim 5, wherein the second conductive layer pattern comprises a material having a resistance lower than the first conductive layer pattern.

12. The vertical-type pillar transistor of claim 11, wherein the first conductive layer pattern comprises polysilicon, and the second conductive layer pattern comprises metal or metal silicide.

13. The vertical-type pillar transistor of claim 5, further comprising a spacer provided on both sidewalls of the first conductive layer pattern, the second conductive layer pattern and the hard mask pattern.

14. The vertical-type pillar transistor of claim 13, further comprising
an insulation interlayer covering the substrate and the hard mask pattern; and
a contact plug penetrating the insulation interlayer to be connected to the substrate.

15.-24. (canceled)
